(19) United States
(12) Patent Application Publication
(10) Pub. No.: US 2021/0388686 A1
(43) Pub. Date: Dec. 16, 2021

(54) MUD CIRCULATING DENSITY ALERT

(71) Applicant: ConocoPhillips Company, Houston, TX (US)

(72) Inventor: Yenshou James Chen, Houston, TX (US)

(21) Appl. No.: 17/347,093

(22) Filed: Jun. 14, 2021

Related U.S. Application Data
(60) Provisional application No. 63/038,396, filed on Jun. 12, 2020.

(51) Int. Cl. E21B 21/08; E21B 47/09; E21B 45/00; G08B 21/18

(52) U.S. Cl. CPC E21B 21/08; G08B 21/182; E21B 45/00; E21B 47/09

(57) ABSTRACT

Implementations described and claimed herein provide systems and methods for monitoring real-time drilling parameters. In one implementation, one or more measured parameters including at least a mud weight (MW) of a drilling fluid within a wellbore are received. At least one of a coefficient of performance (COP) cuttings transport ratio, a COP bit equivalent circulation density (ECD), a COP Wilcox ECD, a reverse circulation ECD, or a COP kill mud density (KMD) are determined from the one or more measured parameters. The at least one of the coefficient of performance (COP) cuttings transport ratio, the COP bit equivalent circulation density (ECD), the COP Wilcox ECD, the reverse circulation ECD, or the COP KMD are displayed. An alert is generated when the at least one of the COP cuttings transport ratio, the COP bit ECD, the COP Wilcox ECD, the reverse circulation ECD, or the COP KMD exceeds a predetermined threshold.

### CROSS-REFERENCE TO RELATED APPLICATION

The present application claims the benefit under 35 U.S.C. § 119 to U.S. Provisional Patent Application No. 63/038,396, entitled “Mud Circulating Density Alert” and filed on Jun. 12, 2020, which is incorporated by reference herein in its entirety.

### BACKGROUND

### 1. Field

The present inventive concept relates generally to systems and methods for monitoring real-time drilling parameters.

### 2. Description of Related Art

Hydrocarbon exploration from subterranean formations can implement one or more wellbores into an earthen surface and through at least a portion of a subterranean formation. The formation of one or more wellbores through at least a portion of the subterranean formation conventionally involves a drill string being exposed to varying downhole conditions, which can impact drilling efficiency and/or the overall life expectancy of the drill string.

### SUMMARY

Implementations described and claimed herein address the foregoing by providing systems and methods for monitoring real-time drilling parameters. In one implementation, one or more measured parameters including at least a mud weight (MW) of a drilling fluid within a wellbore are received from a drill string. At least one of a coefficient of performance (COP) cuttings transport ratio, a COP bit equivalent circulation density (ECD), a COP Wilcox ECD, a reverse circulation ECD, or a COP kill mud density (KMD) are determined from the one or more measured parameters. The at least one of the coefficient of performance (COP) cuttings transport ratio, the COP bit equivalent circulation density (ECD), the COP Wilcox ECD, the reverse circulation ECD, or the COP KMD are displayed. An alert is generated when the at least one of the COP cuttings transport ratio, the COP bit ECD, the COP Wilcox ECD, the reverse circulation ECD, or the COP KMD exceeds a predetermined threshold.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

The novel features of the disclosure are set forth with particularity in the appended claims. A better understanding of the features and advantages of the presently disclosed technology will be obtained by reference to the following detailed description that sets forth illustrative examples, in which the principles of the disclosure are utilized, and the accompanying drawings of which:

FIG. 1 is an environmental view of a wellbore operation within a subterranean formation, according to at least one instance of the present disclosure;

FIG. 2 is a diagrammatic view of a control system for a wellbore operation, according to at least one instance of the present disclosure;

FIG. 3 is a graphical illustration of non-Newtonian mud flow models, according to at least one instance of the present disclosure;

FIG. 4 is graphical user interface (GUI) displaying Equivalent Circulating Density (ECD) and cutting transport ratio, according to at least one instance of the present disclosure;

FIG. 5 is a GUI displaying ECD control tip speed and/or trip margin, according to at least one instance of the present disclosure;

FIG. 6 is a GUI displaying ECD control for surge conditions, according to at least one instance of the present disclosure; and

FIG. 7 is a GUI displaying alert conditions, according to at least one instance of the present disclosure.

FIG. 8 illustrates example operations for monitoring real-time drilling parameters.

### DETAILED DESCRIPTION

Aspects of the presently disclosed technology involve systems and methods for monitoring real-time drilling parameters. In one aspect, a drill rig system comprises a drill string operable to form a wellbore through at least a portion of a subterranean environment. The drill string can have a drill bit disposed at a distal end thereof and the drill string can be operable to measure one or more drilling parameters. A drilling fluid can be disposed within at least a portion of the wellbore and have a mud weight (MW). One or more drilling systems can be coupled with the drill string. One or more processors can be operable to execute instructions stored in memory that causes the one or more drilling systems to: receive the one or more measured parameters from the drill string; determine at least one of a coefficient of performance (COP) cuttings transport ratio, a COP bit equivalent circulation density (ECD), a COP Wilcox ECD, a COP KMD, a reverse circulation ECD, a gas cutting percentage of the drilling mud, and/or a bottom hole pressure (BHP) reduction or ECD reduction due to gas cutting of the drilling mud from the one or more measured parameters; and generate an alert when the at least one of the COP cuttings transport ratio, the COP bit ECD, the COP Wilcox ECD, the reverse circulation ECD, the BHP reduction due to gas cutting, the ECD reduction due to gas cutting, the gas cutting percentage, and/or the COP KMD exceeds a predetermined threshold. The alert may be displayed on a graphical user interface (GUI) when the at least one of the COP cuttings transport ratio, the COP bit ECD, the COP Wilcox ECD, the reverse circulation ECD, the BHP reduction due to gas cutting, the ECD reduction due to gas cutting, the gas cutting percentage, and/or the COP KMD exceeds a predetermined threshold.

The one or more measured parameters can include at least one of hole depth, bit position, bit size, bit true vertical depth (TVD), pipe diameter, flow rate in, top drive revolutions per minute (RPM), rate of penetration (ROP), annulus pressure, string speed, pressure at the TVD, back pressure at well head, hydrostatic pressure of uncut mud, and/or MW.

In one example, the COP cuttings transport ratio can be defined as

$$1 - \frac{{V}_{c u t}}{{V}_{a n}} ,$$

where V_{cut} is cuttings transport velocity and Vₐₙ is annular velocity.

COP bit ECD can be defined as

$${Bit}_{E C D} = MW + \frac{\sum Δ Pfric + Psurf}{TVD} ( 19.23 ) + Δ {ρ}_{cuttings load} ,$$

where ΣΔP_{fric}=ΔP_{turbulent/laminar}+ΔP_{surge/swab} and ΔPfric is frictional pressure loss.

The loss in BHP due to gas cutting of drilling fluid (e.g., “mud”) can be defined as

$$hD - P = \frac{n}{100 - n} ln ( P + 1 )$$

where h is depth, D is the hydrostatic pressure of a one-foot column of uncut mud, P is the pressure at depth h due to the mud column only, and n is the percentage of gas cutting in the mud at the well head given a back pressure p; this equation (the “Strong-White” equation) being solved by successive approximations using hD as a first approximation for P on the right-hand side to calculate a first value for loss in BHP, getting a new value of P on the left hand side, and repeating multiple iterations with the new value of P, results in a rapid convergence of pressure loss in atmospheres (atms).

An input may be received to adjust the MW and/or the Equivalent Circulation density of the drilling fluid in response to the alert. The predetermined threshold can be adjustable based on at least one of the subterranean formation, the drill string, and/or the drill bit.

In another example, a non-transitory computer-readable medium comprising executable instructions, which when executed by a processor, cause the processor to: receive one or more measured parameters from a drill string including at least a mud weight (MW) of a drilling fluid within a wellbore; determine at least one of a coefficient of performance (COP) cuttings transport ratio, a COP bit equivalent circulation density (ECD), a reverse circulation ECD, a BHP reduction due to gas cutting, an ECD reduction due to gas cutting, a gas cutting percentage, a COP Wilcox ECD, and/or a COP KMD from the one or more measured parameters; display the at least one of the coefficient of performance (COP) cuttings transport ratio, the COP bit equivalent circulation density (ECD), the COP Wilcox ECD, and/or the COP KMD on a graphical user interface (GUI); generate an alert when the at least one of the COP cuttings transport ratio, the COP bit ECD, the COP Wilcox ECD, and/or the COP KMD exceeds a predetermined threshold.

The processor can further store instructions to display the alert on the graphical user interface (GUI) when the at least one of the COP cuttings transport ratio, COP bit ECD, the BHP reduction due to gas cutting, the ECD reduction due to gas cutting, the gas cutting percentage, COP Wilcox ECD, a reverse circulation ECD, and/or COP KMD exceeds a predetermined threshold. The one or more measured parameters can include at least one of hole depth, bit position, bit size, bit true vertical depth (TVD), pipe diameter, flow rate in, top drive revolutions per minute (RPM), rate of penetration (ROP), annulus pressure, string speed, back pressure at well head, hydrostatic pressure of uncut mud, and/or MW.

The COP cuttings transport ratio can be defined as

$$1 - \frac{{V}_{c u t}}{{V}_{a n}} ,$$

where V_{cut} is cuttings transport velocity and Vₐₙ is annular velocity.

The COP bit ECD can be defined as

$$B i {t}_{E C D} = M W + \frac{ΣΔPfric + Psurf}{T V D} ( 19.23 ) + {Δρ}_{cuttings load} ,$$

where ΣΔP_{fric}=ΔP_{turbulent/laminar}+ΔP_{surge/swab} and ΔPfric is frictional pressure loss.

The loss in BHP due to gas cutting of drilling fluid (e.g., “mud”) can be defined as

$$hD - P = \frac{n}{100 - n} ln ( P + 1 )$$

where h is depth, D is the hydrostatic pressure of a one-foot column of uncut mud, P is the pressure at depth h due to the mud column only, and n is the percentage of gas cutting in the mud at the well head given a back pressure p; this formula (the “Strong-White” formula) being solved by successive approximations using hD as a first approximation for P on the right-hand side to calculate a first value for loss in BHP, getting a new value of P on the left hand side, and repeating multiple iterations with the new value of P, results in a rapid convergence of pressure loss in atms.

The processor can further store instructions to receive an input to adjust at least one of the MW and/or the COP bit equivalent circulation density of the drilling fluid in response to the alert. The processor can further store instructions to determine a drilling fluid model parameter. The predetermined threshold can be adjustable based on at least one of the subterranean formation, the drill string, and/or the drill bit.

### I. Terminology

As used herein, the terms “comprises,” “comprising,” “includes,” “including,” “has,” “having” or any other variation thereof, are intended to cover a non-exclusive inclusion. For example, a process, product, article, or apparatus that comprises a list of elements is not necessarily limited only those elements but can include other elements not expressly listed or inherent to such process, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term substantially, as used herein, is defined to be essentially conforming to the particular dimension, shape or other word that substantially modifies, such that the component need not be exact. For example, substantially cylindrical means that the object resembles a cylinder, but can have one or more deviations from a true cylinder.

Additionally, any examples or illustrations given herein are not to be regarded in any way as restrictions on, limits to, or express definitions of, any term or terms with which they are utilized. Instead these examples or illustrations are to be regarded as being described with respect to one particular example and as illustrative only. Those of ordinary skill in the art will appreciate that any term or terms with which these examples or illustrations are utilized encompass other examples as well as implementations and adaptations thereof which can or cannot be given therewith or elsewhere in the specification and all such examples are intended to be included within the scope of that term or terms. Language designating such non-limiting examples and illustrations includes, but is not limited to: “for example,” “for instance,” “e.g.,” “In some examples,” and the like.

Although the terms first, second, etc. can be used herein to describe various elements, components, regions, layers and/or sections, these elements, components, regions, layers and/or sections should not be limited by these terms. These terms are only used to distinguish one element, component, region, layer, or section from another. Thus, a first element, component, region, layer, or section discussed below could be termed a second element, component, region, layer, or section without departing from the teachings of the present inventive concept.

### II. General Architecture

The systems and methods disclosed herein relate to monitoring and/or controlling downhole mud density circulation within a predetermined threshold to maintain efficient drilling operations. A mud density can include a cutting transport ratio, an equivalent circulating density (ECD) ratio at bit depth, an ECD ratio at Wilcox depth, a BHP reduction due to gas cutting, an ECD reduction due to gas cutting, a gas cutting percentage, and/or a kick detection during connection. The systems and methods of the present disclosure determine in real time one or more downhole mud density parameters for operation within a predetermined threshold, and operably alert a user if one or more of the downhole parameters exceeds the predetermined threshold.

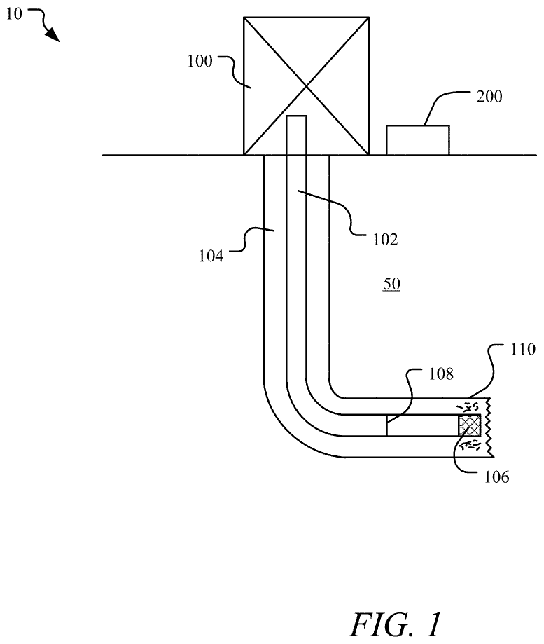

FIG. 1 illustrates a wellbore drilling operation within a subterranean formation according to at least one instance of the present disclosure. A drill site 10 can have drilling rig 100 including a drill string 102 operable to form a wellbore 104 within at least a portion of a subterranean formation 50. The drill string 102 can include a drill bit 106 and/or a mud motor 108 operable to circulate a drilling fluid (e.g. drilling mud) through at least a portion of the wellbore 102 to enhance a performance of the drilling rig 100 operation.

The drilling fluid can be circulated within the wellbore 102 during the drilling operation to remove cuttings 110 or portions of the subterranean formation 50 removed by the drill bit 106, thereby providing the drill bit 106 a fresh and clean working environment. The drilling fluid can be operable to circulate the cuttings 110 from adjacent to the drill bit 106 to an uphole location adjacent the drilling rig 100.

The drilling fluid can have a density operable to enhance the performance of the drill string 102 and/or the drill bit 106, thereby increasing the rate of penetration (ROP) through the subterranean formation 50. Adjustment of the drilling fluid density can occur during a drilling operation to maintain optimum efficiency and prevent unnecessary wear and tear on the drill string 102 and/or the drill bit 106 as the wellbore 104 is formed. The adjustment of the drilling fluid density can assist in the efficiency in removing cuttings 110 away from the drill bit 106.

The drilling rig 100 can include one or more drilling systems 200 operable to manage the drill string 102 to maintain efficient performance throughout the drilling operation. The one or more drilling systems can include an equivalent circulating density (ECD) module operable to determine the ECD within the wellbore 104 during the drilling operation. ECD can be a measurement of drilling fluid (e.g. drilling mud) density and the frictional pressure loss fluid under flow conditions determined by the Reynolds Number (Re) and expressed in terms of the fluid velocity and apparent viscosity (or plastic viscosity (PV) and yield point (YP)). The drilling fluid is deemed to have a laminar flow for an Re<2,100, transition flow for an Re=2,100-4,000, and a turbulent flow for an Re>4,000. The ECD module may take into account a percentage of gas by volume in the fluid (e.g., gas cutting), such as by aeration, and its effect on the ECD and/or a bottom hole pressure (BHP).

The one or more systems can be operable to determine a coefficient of performance (COP) for one or more downhole parameters of the drilling operation. A COP of cutting transport ratio can be efficiency of cuttings 110 carried by the drilling fluid. The COP of cutting transport ratio can be

$$1 - \frac{{V}_{c u t}}{{V}_{a n}} ,$$

wherein V_{cut} is cuttings transport velocity, and Vₐₙ is annular velocity (e.g. speed of fluid movement in a column). v_{cut} can be a function of rate of penetration, hole size, and pipe outer diameter (OD) defined as

$${V}_{c u t} = \frac{R O P}{36 {⌈ 1 - \frac{{D}_{pipe}}{{D}_{h o l e}} ⌉}^{2} [ 0.64 + \frac{18.16}{R O P} ]} ,$$

while Vₐₙ can be a function of W, bit size, and pipe OD defined as

$${V}_{a n} = 24.5 [ \frac{Q}{{D}_{h o l e}^{2} - {D}_{pipe}^{2}} ] .$$

In instances of a drill string having a high angle, Vₛₚᵢᵣₐₗ can be incorporated, wherein Vₛₚᵢᵣₐₗ is defined as

$$\frac{π}{12} * R P M * {D}_{p i p e} * sin θ ,$$

and the COP cutting transport percentage is

$$1 - \frac{{V}_{c u t}}{{( {V}_{a n}^{2} + {V}_{spiral}^{2} )}^{0.5}} .$$

COP of bit ECD can be the equivalent circulating density of the drilling fluid at bit depth (e.g. the depth within the subterranean formation of the drill bit 106). The COP bit ECD can be a function of drilling fluid weight, frictional pressure loss, annual pressure, and bit position and defined as

$${Bit}_{E C D} = MW + \frac{\sum Δ Pfric + Psurf}{TVD} ( 19.23 ) + Δ {ρ}_{cuttings load} ,$$

where ΣΔP_{fric}=ΔP_{turbulent/laminar}+ΔP_{surge/swab}. COP of Weak zone ECD can be the equivalent circulating density of the drilling fluid at the weak zone depth and follow the same function above for Bit ECD limited to the Weak Zone Depth. A COP KMD can be a kick detection alert during the drilling operation. The reverse circulation ECD can be the ECD as the drilling fluid circulates in reverse direction, from the annulus to the pipe, and with a BHP defined as the hydrostatic pressure plus the pressure generated by the pump minus the annular pressure loss. Additionally, the COP of bit ECD can be affected by a reduction in BHP caused by gas cutting in the drilling fluid, as defined by the Strong-White equation:

$$h D - P = \frac{n}{100 - n} ln ( P + 1 )$$

where h is depth, D is the hydrostatic pressure of a one-foot column of uncut mud, P is the pressure at depth h due to the drilling fluid column only, and n is the percentage of gas cutting in the drilling fluid at the well head given a back pressure p; this equation (the “Strong-White” equation) being solved by successive approximations using hD as a first approximation for P on the right-hand side to calculate a first value for loss in BHP, getting a new value of P on the left hand side, and repeating multiple iterations with the new value of P, results in a rapid convergence of the pressure loss in atms.

The drill string 102 can encounter various downhole conditions during a drilling operation kick back and/or ballooning. Kick can be defined as the unwanted flow or entry of fluids into a wellbore 104 from the subterranean formation 50 during the drilling operation. A gas kick can be defined as the unwanted flow or entry of gas into the wellbore 104 from the subterranean formation 50 during the drilling operation. Ballooning can be defined as the unwanted loss of fluids into the subterranean formation 50 during a drilling operation caused by an over-pressure arrangement followed by the flow back of the fluid when the pressure is reduced.

The one or more drilling systems 200 can be operable to monitor the one or more downhole parameters during a drilling operation to maintain an efficient drilling operation through control of one or more of the COP cuttings transport ratio, COP bit ECD, COP Wilcox ECD, the reverse circulation ECD, the BHP, back pressure at the well head, the gas cutting percentage, and/or COP KMD.

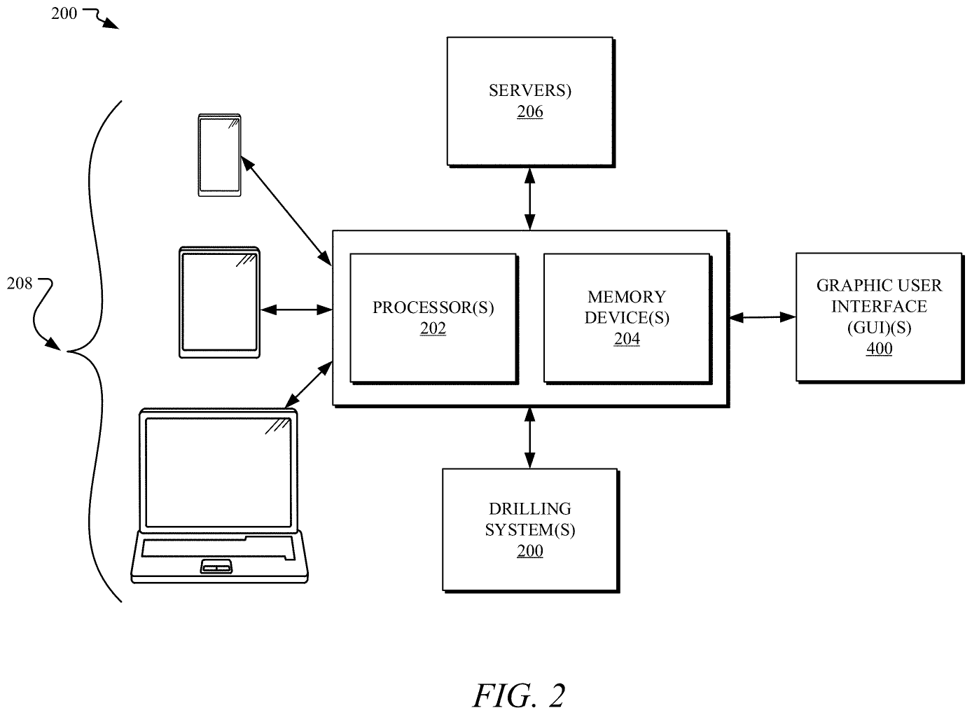

FIG. 2 illustrates a diagrammatic view of one or more drilling systems, according to at least one instance of the present disclosure. The one or more drilling systems 200 can include one or more processors 202 and/or one or more memories 204 operably coupled with the drilling rig 100. The one or more processors 202 can be microprocessors, central processing units (CPUs), graphics processing units (GPUs), and/or any combination thereof. The one or more memories 204 can include read-only memory (ROM), random access memory (RAM), hard disk drives (HDDs), solid state drives (SSDs), and/or any combination thereof. The one or more drilling systems 200 can be operably coupled with the drilling rig 100 to receive one or more downhole parameters including, but not limited to, hole depth, bit position, bit size, bit true vertical depth (TVD), pipe diameter, flow rate in, top drive revolutions per minute (RPM), ROP, annulus pressure, string speed, back pressure at the well head, the BHP, mud weight (MW), and/or any other downhole measurement. The one or more drilling systems 200 can be operable to determine one or more of the COP cuttings transport ratio, COP bit ECD, COP Wilcox ECD, reverse circulation ECD, gas cutting percentage, BHP reduction due to gas cutting, ECD reduction due to gas cutting, and/or COP KMD. A COP MW Balance Indicator can be operable to determine whether over/under-balance drilling is occurring through relative changes of gas ratios from returning drilling fluid. The COP MW Balance can include a Wetness Ratio and/or a Balance Ratio.

The gas wetness ratio can be a relationship between Methane (C₁), Ethane (C₂), Propane (C₃), Butane (C₄), and/or Pentane (C₅), as defined by:

$$Wetness Ratio = \frac{{C}_{2} + {C}_{3} + {C}_{4} + {C}_{5}}{{C}_{1} + {C}_{2} + {C}_{3} + {C}_{4} + {C}_{5}}$$

The one or more drilling systems 200 can further track a balance ratio between Methane (C₁), Ethane (C₂), Propane (C₃), Iso-Butane (IC₄), Nor-Butane (NC₄) and/or Pentane (C₅), defined by:

$$Balance Ratio = \frac{{C}_{1} + {C}_{2}}{{C}_{3} + {IC}_{4} + N {C}_{4} + {C}_{5}}$$

The one or more drilling systems 200 can be operable to generate an alert if one or more of the COP cuttings transport ratio, COP bit ECD, COP Wilcox ECD, reverse circulation ECD, gas cutting percentage, BHP reduction due to gas cutting, ECD reduction due to gas cutting, and/or COP KMD exceed a predetermined threshold. The predetermined threshold can be user defined and/or adjusted based on the drilling operation, drill string 102, and/or the subterranean formation.

A server 206 can be coupled with the one or more drilling systems 200 to store the one or more drilling parameters and/or the one or more of the COP cuttings transport ratio, COP bit ECD, COP Wilcox ECD, reverse circulation ECD, gas cutting percentage, BHP reduction due to gas cutting, ECD reduction due to gas cutting, and/or COP KMD. In at least one instance, the server 206 is a cloud-based storage device operable to store one or more elements of the one or more drilling systems 200.

The one or more drilling systems 200 can operably coupled with an electronic device 208. The electronic device 208 can be a computer, tablet, cellphone, and/or other personal electronic device operable to receive one or more alerts thereon from the one or more drilling systems 200. The one or more drilling systems 200 can be operable to: determine one or more of the COP cuttings transport ratio, COP bit ECD, COP Wilcox ECD, reverse circulation ECD, gas cutting percentage, BHP reduction due to gas cutting, ECD reduction due to gas cutting, and/or COP KMD; generate an alert if a predetermined threshold is exceeded; and transmit the alert to the electronic device 208. In at least one instance, the electronic device 208 can be a personal electronic device of a drilling operator.

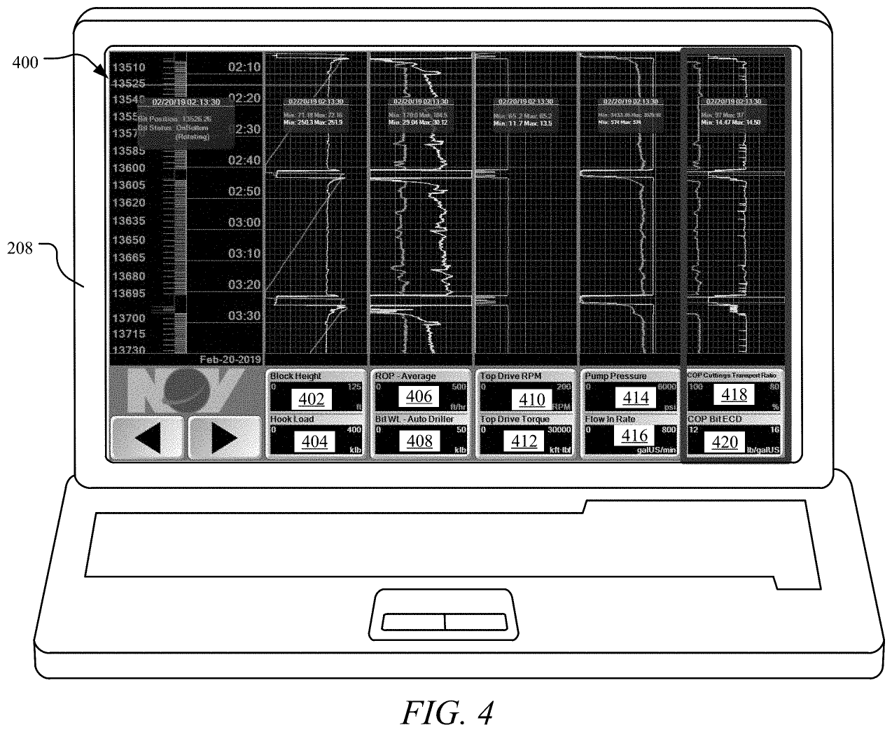

The one or more drilling systems 200 can generate a graphical user interface (GUI) 400 operable to display one or more of the COP cuttings transport ratio, COP bit ECD, COP Wilcox ECD, reverse circulation ECD, gas cutting percentage, BHP reduction due to gas cutting, ECD reduction due to gas cutting, and/or COP KMD. The GUI, described in more detail below with respect to FIG. 4, can also be operable to display one or more alerts.

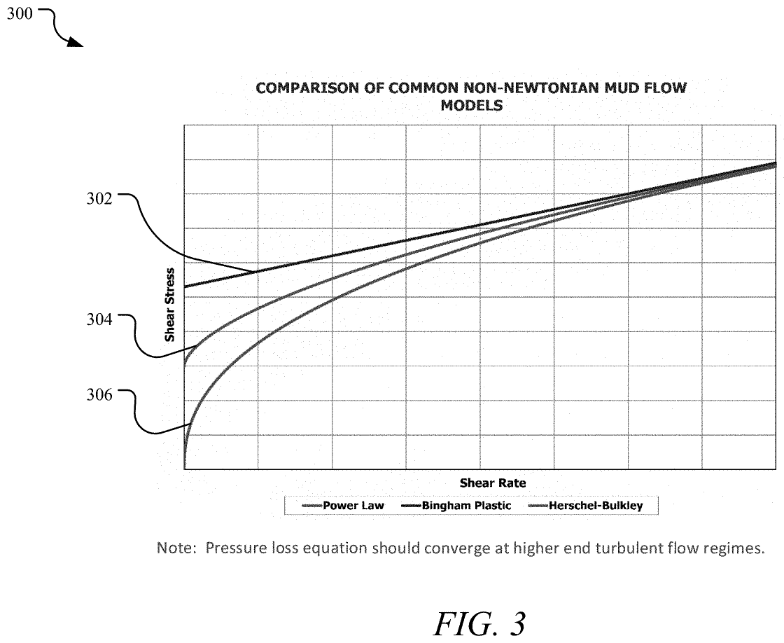

FIG. 3 illustrates a fluid modeling 300 for common non-Newtonian fluids according to at least one instance of the present disclosure. A comparison of common non-Newtonian fluids can be displayed for modeling potential drilling fluids within a drilling operation as a relationship between shear stress and shear rate. As can be appreciated in FIG. 2, the three fluid type models: Bingham Plastic Model 302; the Power Law Model 304; and the Herschel Bulkley Model 306 converge at higher end turbulent flows. The drilling fluid can be modelled according to a fluid type and an appropriate fluid mode. A Bingham Plastic Model 302 can be implemented for fluid type 1, which can provide a substantially linear relationship between shear stress and shear rate. A Power Law model 304 can be implemented for fluid type 2 and illustrate a shear thinning effect on a drilling fluid, and a Herschel Bulkley Model 306 can be implemented for fluid type 3 and illustrate a constant of proportionality, while the flow index measures the degree to which the drilling fluid is shear thinning or shear thickening. The one or more drilling systems 200 can be operable to select an appropriate fluid type based on the implemented drilling fluid and the model applicable thereto. The one or more drilling systems 200 can default to a fluid type 3, and prompt a user input for LSYP. Otherwise, a default value will be implemented.

The applicable fluid model for the drilling fluid can determine one or more constants associated with the applicable fluid type. In at least one instance, fluid type 1 (Bingham Plastic Model) can include a low shear yield point (LSYP) of 2, a plastic viscosity (PV) of 20, a Wilcox depth of 7500, and a yield point (YP) of 8. The one or more drilling systems 200 can determine the PV and/or YP at a given Wilcox depth, and the PV, YP, and/or LSYP can be updated at predetermined interval (e.g. hourly, daily, weekly, etc.).

FIG. 4 illustrates a graphical user interface (GUI) 400 representation of COP Cutting Transport Ratio determined for one or more drilling systems, according to at least one instance of the present disclosure. The one or more drilling systems 200 can display a GUI including one or more parameters of the drilling operation. As can be appreciated in FIG. 4, the GUI 400 can display a Block Height 402, Hook Load 404, Average ROP 406, Bit Weight 408, Top Drive RPM 410, Top Drive Torque 412, Pump Pressure 414, Flow In Rate 416, COP Cutting Transport Ratio 418, and/or COP Bit ECD 420. The GUI 400 can also display a reverse circulation ECD, a gas cutting percentage and/or indications of an effect of the gas cutting percentage on the other parameters presented on the GUI.

The one or more drilling system 200 and/or the GUI 400 can be operable to prevent pack-off and/or break down at the shoe by determining the COP Cutting Transport Ratio 418 and/or the COP Bit ECD 420 and providing an alert if the COP Cutting Transport Ratio 418 and/or the COP Bit ECD 420 exceed a predetermined threshold. Pack-off can be experienced with a drilling fluid is partially and/or completely blocked. The one or more drilling systems 200 and/or the GUI 400 can prevent pack-off by detailing the COP Cutting Transport Ratio 418 and/or COP Bit ECD 420. As can be appreciated in FIG. 4, the COP Cutting Transport Ratio 418 is greater than 90%, which indicates effective circulation of the drilling fluid. In at least one instance, if the COP Cutting Transport Ratio 418 falls below a predetermined threshold, the one or more drillings systems 200 and/or processors can be operable to generate an alert to an operator requiring an adjustment to one or more drilling parameter including the drilling fluid, the gas cutting percentage, and/or the ECD. The Bit ECD can be managed with Managed Pressure Drilling to prevent under pressure and/or over pressure events.

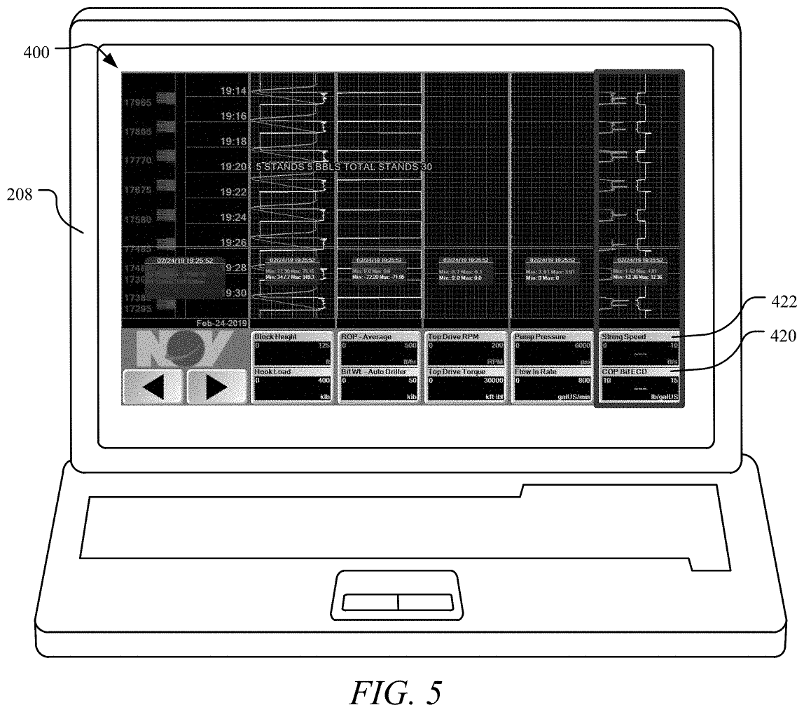

FIG. 5 illustrates a GUI 400 representation of string speed determined by one or more drilling systems, according to at least one instance of the present disclosure. As can be appreciated in FIG. 5, the GUI 400 can be operable to illustrate a string speed 422 during pulling out of hole (POOH). The string speed 422 illustrates the movement of the drill string 102 within the wellbore 104. The one or more drilling systems 200 can utilize the COP Bit ECD 420 to help determine the string speed 422 and trip margin. The trip margin can be the necessary additional mud weight (MW) to balance the formation pressure caused by swabbing during POOH. The one or more drilling systems 200 can monitor change in COP Bit ECD 420 during POOH and can be operable to generate an alert and/or GUI 400 alert for an operator if the COP Bit ECD exceeds a predetermined threshold.

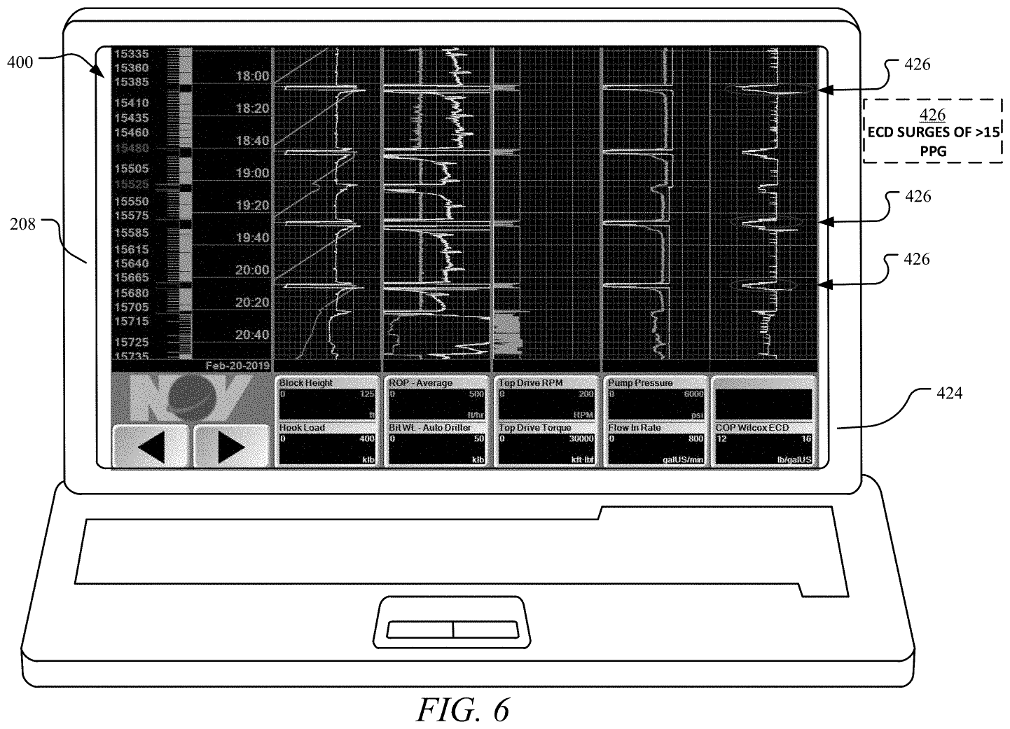

FIG. 6 illustrates a GUI representation of COP Wilcox ECD determined by one or more drilling systems, according to at least one instance of the present disclosure. The one or more drilling system 200 and/or the COP Wilcox ECD can be operable to monitor RIH and/or back to bottom scenarios to prevent surge, which is an increase in bottom hole pressure due to the drill string 102 being RIH. As can be appreciated in FIG. 6, the GUI 400 can illustrate surges in the COP Wilcox ECD 424 exceeding a predetermined threshold 426 representing a surge due to the drill string 102 RIH too fast. The surges in the COP Bit ECD 420 can be greater than 15 pounds per gallon (ppg), and thus the one or more drilling systems 200 and/or at least one processor generates an alert.

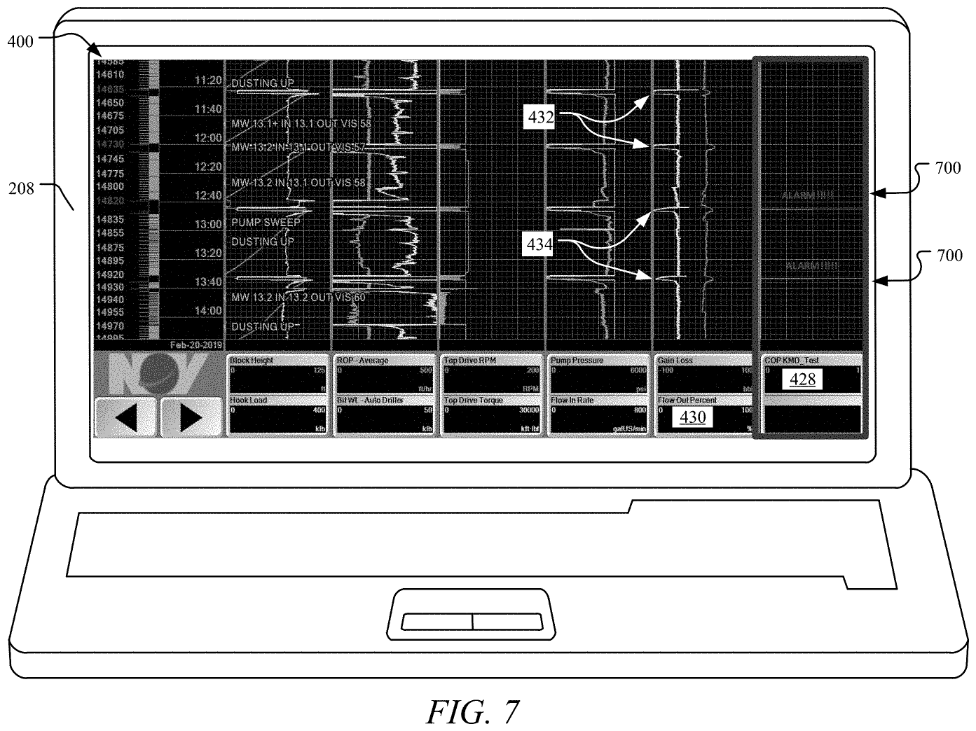

FIG. 7 illustrates a GUI representation of COP KMD determined by one or more drilling system, according to at least one instance of the present disclosure. The GUI 400 can additionally provide feedback and/or alerts if a COP KMD 428 exceeds a predetermined threshold indicative of ballooning and/or kick. Ballooning and/or kick during a drilling operation can lead to damage and/or excessive wear and tear on equipment. The one or more drilling systems 200 operable to provide a user alert 700 if COP KMD 428 exceeds a predetermined threshold can prevent the ballooning and/or kick, thus increasing the useful life of the drilling string 102 and increasing the efficiency of the drilling operation.

A flow out rate percentage 430 can be displayed and determined by the one or more drilling systems 200. The flow out rate percentage 430 can indicate the loss of the drilling fluid to the formation, thus increasing the risk of kick and/or ballooning. The one or more drilling systems 200 and/or processors can be operable to generate an alert based on the COP KMD 428 exceeding a predetermined threshold, thereby alerting an operator of the increase risk of kick and/or ballooning. The ECD can be adjusted to lower the risk of kick and/or ballooning and stop the outflow of the drilling fluid to the formation.

Gas wetness and/or a gas Wetness Ratio within the drilling fluid can provide indications of a kick by the COP KMD 428. Gases such as Methane (C₁), Ethane (C₂), Propane (C₃), Butane (C₄), Pentane (C₅), Nor-Butane (NC₄), Iso-Butane (IC₄), Nor-Pentane (NC₄), and/or Iso-Pentane (IC₅) can flow from the subterranean formation and into the wellbore, thereby entering the drilling fluid. The one or more drilling systems 200 can be operable to determine the fluid type (C1 to C5) from returning drilling fluid to identify relative changes in the gas-liquid ratio and/or wetness.

The Wetness Ratio and/or the Balance Ratio can assist the one or more drilling systems 200 and/or processors to detect ballooning, gas pocket, and/or influx, thus indicating the COP KMD 428 to indicate a kick. The Wetness Ratio and/or the Balance Ratio can be implemented to determine a COP MW Balance Indicator to determine the cause of the kick indicated by COP KMD 428. The COP MW Balance can be reference to a mud weight balance in view of the Wetness Ratio and/or the Balance Ratio.

The wetness ratio and balance ratio, relative to the other, can provide an indication as to whether the COP KMD 428 indicates a kick. In some instances, a high wetness ratio and a low balance ratio can indicate a divergence between the two ratios along with an underbalanced drilling situation, thus the COP KMD 428 can indicate a kick due to ballooning and/or an influx from the SRV. In other instances, a low wetness ratio and a high balance ratio can indicate convergence along with a near balanced-overbalanced drilling situation, thus the COP KMD 428 can indicate no kick due to drilling case and/or background gas. In yet other instances, a high wetness ratio and a high balance ratio, which is unlikely, can indicate corresponding ratios and an underbalanced-near balanced drilling situation, thus the COP KMD 428 can indicate a kick due to a gas pocket and/or influx. In yet other instances, a low wetness ratio and a low balance ratio, which is unlikely, can indicate corresponding ratios and an near balanced-overbalanced drilling situation, thus the COP KMD 428 can indicate a kick due to no gas pocket and/or no background gas.

While the COP KMD 428 can indicate a kick detection due to gas influx and/or ballooning, a COP MW Balance indicator can determine whether the kick is caused by gas influx and/or ballooning through the implementation of the gas ratios (e.g. wetness ratio, balance ratio).

Therefore, rather than looking at two curves (wetness ratio and/or balance ratio), the one or more drilling systems 200 can formulate an equation to normalize the severity of divergence, and thus provide information on whether drilling fluid (e.g. mud weight) is over- or under-balanced.

As can be appreciated in FIG. 7, the flow out rate percentage 430 can have a substantially buttress pattern 432 with spikes in outflow followed by brief steady outflow in which drilling fluid flows into the formation, but the one or more drilling systems 200 and/or processors do not generate an alert because the one or more drilling systems 200 determine ballooning and/or kick are not increased. The flow out rate percentage 430 can have a substantially “shark fin” pattern 434 with large spike in flow out rate percentage 430, which the one or more drilling systems 200 can identify as increasing kick and/or ballooning. The one or more drilling systems 200 and/or processors can be operable to generate an alert and/or based on the COP KMD 428 which exceeds the predetermined threshold during substantially “shark fin” pattern 434 increases in the flow out rate percentage 430, thus requiring action to prevent kick and/or ballooning.

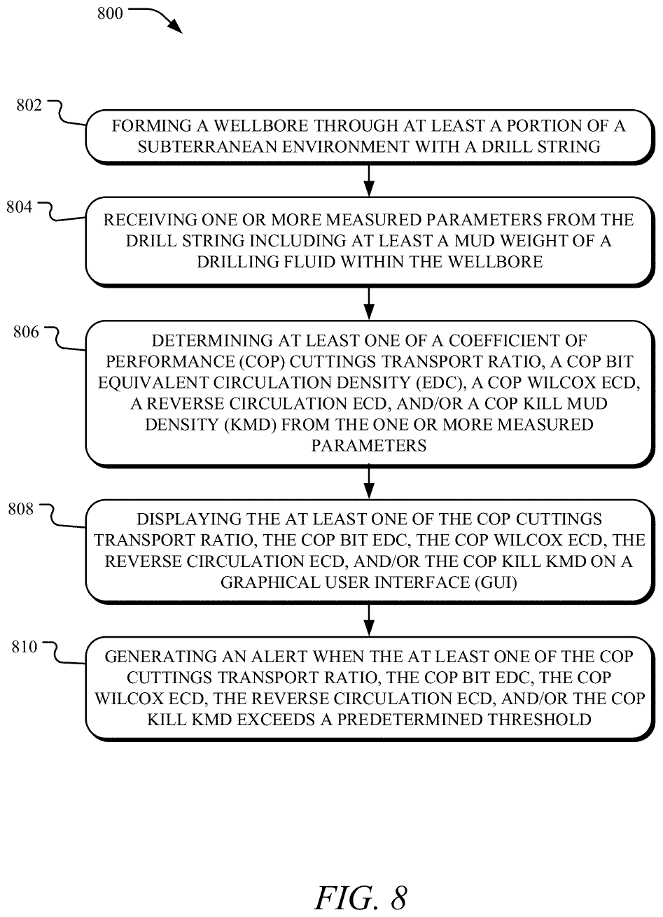

FIG. 8 illustrates an example method 800 that can be performed by any of the systems discussed herein. The method 800 may include, at step 802, forming the wellbore 104 through at least a portion of a subterranean environment with the drill string 102. The method may include, at step 804, receiving one or more measured parameters from the drill sting 102 including at least a mud weight of a drilling fluid within the wellbore 104. The method may include, at step 806, determining at least one of the COP cuttings transport the COP bit EDC, the COP Wilcox ECD, the reverse circulation ECD, and/or the COP KMD from the one or more measured parameters. The method may include, at step 808, displaying the at least one of the COP cuttings transport the COP bit EDC, the COP Wilcox ECD, the reverse circulation ECD, and/or the COP KMD on the GUI 400. The method may include, at step 810, generating an alert when the at least one of the COP cuttings transport the COP bit EDC, the COP Wilcox ECD, the reverse circulation ECD, and/or the COP KMD exceeds a predetermined threshold. In some examples, the steps 800-810 of the method 800 may be performed in a different order than that presented in FIG. 8. Moreover, any of the steps the steps 800-810 of the method may be combined, omitted, repeated, and/or performed using multiple drilling systems 200 operating together during the sequence of steps.

Any ranges cited herein are inclusive. The terms “substantially” and “approximately” and “about” and similar terms are used to describe and account for small fluctuations. For example, these terms can refer to ±5%. It is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order and are not necessarily meant to be limited to the specific order or hierarchy presented.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A drill rig system comprising:
a drill string operable to form a wellbore through at least a portion of a subterranean environment, the drill string having a drill bit disposed at a distal end;
a drilling fluid disposed within at least a portion of the wellbore, the drilling fluid have a mud weight (MW), the drill string operable to measure one or more drilling parameters including the MW; and
one or more drilling systems associated with the drill string, the one or more drilling systems configured to determine at least one of a coefficient of performance (COP) cuttings transport ratio, a COP bit equivalent circulation density (ECD), a COP Wilcox ECD, a reverse circulation ECD, or a COP kill mud density (KMD) from the one or more measured parameters, the one or more drilling systems configured to generate an alert when the at least one of the COP cuttings transport ratio, the COP bit ECD, the COP Wilcox ECD, the reverse circulation ECD, or the COP KMD exceeds a predetermined threshold.

2. The drill rig system of claim 1, wherein the alert is presented with a graphical user interface (GUI).

3. The drill rig system of claim 1, wherein the one or more measured parameters includes at least one of hole depth, bit position, bit size, bit true vertical depth (TVD), pipe diameter, flow rate in, top drive revolutions per minute (RPM), rate of penetration (ROP), annulus pressure, string speed, gas cutting percentage, or the MW.

4. The drill rig system of claim 1, wherein the COP cuttings transport ratio is defined as
$$1 - \frac{{V}_{c u t}}{{V}_{a n}} ,$$
wherein V_{cut} is cuttings transport velocity and Vₐₙ is annular velocity.

5. The drill rig system of claim 1, wherein the COP bit ECD is defined as
$${Bit}_{E C D} = MW + \frac{\sum Δ Pfric + Psurf}{TVD} ( 19.23 ) + Δ {ρ}_{cuttings load} ,$$
where ΣΔP_{fric}=ΔP_{turbulent/laminar}+ΔP_{surge/swab} and ΔPfric is frictional pressure loss.

6. The drill rig system of claim 1, wherein the one or more drilling systems receive an input to adjust at least one of the MW or the Equivalent Circulation density of the drilling fluid in response to the alert.

7. The drill rig system of claim 1, wherein the one or more drilling systems are further configured to determine a drilling fluid model parameter.

8. The drill rig system of claim 1, wherein the predetermined threshold is adjustable based on at least one of the subterranean formation, the drill string, or the drill bit.

9. One or more tangible non-transitory computer-readable storage media storing computer-executable instructions for performing a computer process on a computing system, the computer process comprising:
receiving one or more measured parameters from a drill string including at least a mud weight (MW) of a drilling fluid within a wellbore;
determining at least one of a coefficient of performance (COP) cuttings transport ratio, a COP bit equivalent circulation density (ECD), a COP Wilcox ECD, a reverse circulation ECD, or a COP kill mud density (KMD) from the one or more measured parameters;
generating a graphical user interface (GUI) including the at least one of the coefficient of performance (COP) cuttings transport ratio, the COP bit equivalent circulation density (ECD), the COP Wilcox ECD, the reverse circulation ECD, or the COP KMD; and
generating an alert when the at least one of the COP cuttings transport ratio, the COP bit ECD, the COP Wilcox ECD, the reverse circulation ECD, or the COP KMD exceeds a predetermined threshold.

10. The or more tangible non-transitory computer-readable storage media of claim 9, wherein the computer process further comprises:
outputting the alert for display on the GUI when the at least one of the COP cuttings transport ratio, the COP bit ECD, the COP Wilcox ECD, the reverse circulation ECD, and/or the COP KMD exceeds the predetermined threshold.

11. The or more tangible non-transitory computer-readable storage media of claim 9, wherein the one or more measured parameters includes at least one of hole depth, bit position, bit size, bit true vertical depth (TVD), pipe diameter, flow rate in, top drive revolutions per minute (RPM), rate of penetration (ROP), annulus pressure, string speed, gas cutting percentage, or the MW.

12. The or more tangible non-transitory computer-readable storage media of claim 9, wherein the COP cuttings transport ratio is defined as
$$1 - \frac{{V}_{c u t}}{{V}_{a n}} ,$$
wherein V_{cut} is cuttings transport velocity and Vₐₙ is annular velocity.

13. The or more tangible non-transitory computer-readable storage media of claim 9, wherein the COP bit ECD is defined as
$${Bit}_{E C D} = MW + \frac{\sum Δ Pfric + Psurf}{TVD} ( 19.23 ) + Δ {ρ}_{cuttings load} ,$$
where ΣΔP_{fric}=ΔP_{turbulent/laminar}+ΔP_{surge/swab} and ΔPfric is frictional pressure loss.

14. The or more tangible non-transitory computer-readable storage media of claim 9, wherein the computer process further comprises:
receiving an input to adjust at least one of the MW and/or the COP bit equivalent circulation density of the drilling fluid in response to the alert.

15. The or more tangible non-transitory computer-readable storage media of claim 9, wherein the computer process further comprises:
determining a drilling fluid model parameter.

16. The or more tangible non-transitory computer-readable storage media of claim 9, wherein the predetermined threshold is adjustable based on at least one of the subterranean formation, the drill string, or the drill bit.

17. A method comprising:
receiving one or more measured parameters from a drill string including at least a mud weight (MW) of a drilling fluid within a wellbore;
determining at least one of a coefficient of performance (COP) cuttings transport ratio, a COP bit equivalent circulation density (ECD), a COP Wilcox ECD, a reverse circulation ECD, or a COP kill mud density (KMD) from the one or more measured parameters;
displaying the at least one of the coefficient of performance (COP) cuttings transport ratio, the COP bit equivalent circulation density (ECD), the COP Wilcox ECD, the reverse circulation ECD, or the COP KMD on a graphical user interface (GUI); and
generating an alert when the at least one of the COP cuttings transport ratio, the COP bit ECD, the COP Wilcox ECD, the reverse circulation ECD, or the COP KMD exceeds a predetermined threshold.

18. The method of claim 17, wherein the one or more measured parameters includes at least one of hole depth, bit position, bit size, bit true vertical depth (TVD), pipe diameter, flow rate in, top drive revolutions per minute (RPM), rate of penetration (ROP), annulus pressure, string speed, gas cutting percentage, or the MW.

19. The method of claim 18, wherein the one or more measured parameters comprises the gas cutting percentage, and the at least one of the COP cuttings transport ratio, the COP bit ECD, the COP Wilcox ECD, the reverse circulation ECD, or a COP KMD being adjusted based at least partly on the gas cutting percentage.

20. The method of claim 17, further comprising:
adjusting a gas cutting percentage of the drilling fluid at least partly in response to the alert.
